(19) United States
(12) Patent Application Publication
(10) Pub. No.: US 2013/0026531 A1
(43) Pub. Date: Jan. 31, 2013

(54) NON-POLAR LIGHT EMITTING DIODE HAVING PHOTONIC CRYSTAL STRUCTURE AND METHOD OF FABRICATING THE SAME

(71) Applicants: Won Cheol Seo, Ansan-si (KR); Joo Won Choi, Ansan-si (KR)

(72) Inventors: Won Cheol Seo, Ansan-si (KR); Joo Won Choi, Ansan-si (KR)

(73) Assignee: SEOUL OPTO DEVICE CO., LTD., Ansan-si (KR)

(21) Appl. No.: 13/360,471

(22) Filed: Jan. 27, 2012

(30) Foreign Application Priority Data
Feb. 11, 2011 (KR) 10-2011-0012301

(51) Int. Cl. H01L 33/62

(52) U.S. Cl. 257/99; 438/46; 257/E33.066

(57) ABSTRACT

A non-polar light emitting diode (LED) having a photonic crystal structure and a method of fabricating the same. A non-polar LED includes a support substrate, a lower semiconductor layer positioned on the support substrate, an upper semiconductor layer positioned over the lower semiconductor layer, a non-polar active region positioned between the lower and upper semiconductor layers, and a photonic crystal structure embedded in the lower semiconductor layer. The photonic crystal structure embedded in the lower semiconductor layer may improve the light emitting efficiency by preventing the loss of light in the semiconductor layer, and the photonic crystal structure is used to improve the polarization ratio of the non-polar LED.

### CROSS-REFERENCE TO RELATED APPLICATION

This application claims priority from and the benefit of Korean Patent Application No. 10-2011-0012301, filed on Feb. 11, 2011, which is hereby incorporated by reference for all purposes as if fully set forth herein.

### BACKGROUND

1. Field

Exemplary embodiments of the present invention relate to a non-polar light emitting diode (LED) and a method of fabricating the same, and more particularly, to a non-polar LED having a photonic crystal structure and a method of fabricating the same.

2. Discussion of the Background

GaN-based light emitting diodes (LEDs) are widely used for display elements and backlights. Further, these LEDs have less electric power consumption and a longer lifespan than conventional light bulbs or fluorescent lamps, so that their application areas have been expanded for general illumination while substituting for conventional incandescent bulbs and fluorescent lamps.

In general, a GaN-based nitride semiconductor is grown on a heterogeneous substrate, such as sapphire or silicon carbide substrate. An LED is fabricated using such nitride semiconductor layers.

Meanwhile, since a nitride semiconductor is generally grown on a c-plane (0001) of a sapphire substrate, the nitride semiconductor has piezoelectric properties. A strong polarization field is generated in an active region having a multiple quantum well structure due to the piezoelectric properties and, therefore, it is difficult to increase the thickness of a well layer. Further, a light emitting recombination rate is decreased and, therefore, improvement in light emitting efficiency is limited.

Recently, studies have been conducted to develop a method of fabricating a non-polar or semi-polar LED by growing a nitride semiconductor on a-plane (1120) or m-plane (1100) so as to prevent the polarization field from being generated. It is expected that the light emitting efficiency of the non-polar LED will be improved by increasing its light emitting recombination rate over that of the polar LED which generates the polarization field. Unlike the polar LED, the non-polar LED has a characteristic of emitting a polarized light, which has been reported in Japanese Journal of Applied Physics, Vol. 46, No. 42, 2007, pp L1010-L1012. Thus, the polarized light can be appropriately used suitable for various application fields.

However, since the light emitting efficiency of the non-polar LED is currently not higher than that of the polar LED, the light emitting efficiency of the non-polar LED should be increased. In order to use the polarized light, the polarization ratio of the light emitted from the LED should also be increased.

### SUMMARY OF THE INVENTION

Exemplary embodiments of the present invention provide a non-polar light emitting diode (LED) having an improved light emitting efficiency and a method of fabricating the same.

Exemplary embodiments of the present invention also provide a non-polar LED having a new structure and a method of fabricating the same, thereby capable of improving the polarization ratio of the light emitted from the non-polar LED.

Additional features of the invention will be set forth in the description which follows, and in part will be apparent from the description, or may be learned by practice of the invention.

An exemplary embodiment of the present invention discloses a non-polar LED, the non-polar LED including: a support substrate; a lower semiconductor layer disposed on the support substrate; an upper semiconductor layer disposed over the lower semiconductor layer; an active region disposed between the lower and upper semiconductor layers; and a photonic crystal structure embedded in the lower semiconductor layer. The photonic crystal structure may improve the light emitting efficiency by preventing the loss of light in the semiconductor layers, and improve the polarization ratio of the non-polar LED.

An exemplary embodiment of the present invention also discloses a method of fabricating a non-polar LED, the method including: forming a first conductive semiconductor layer, a non-polar active region and a second conductive semiconductor layer on a growth substrate; forming a pattern of voids by partially patterning the second conductive semiconductor layer; forming a second conductive contact layer for covering the pattern of the voids; forming an ohmic contact layer on the second conductive contact layer; forming a support substrate on the ohmic contact layer; and removing the growth substrate and exposing the first conductive semiconductor layer. A photonic crystal structure is provided by the pattern of the voids, and thus it is possible to fabricate the non-polar LED having the photonic crystal structure embedded in the lower semiconductor layer between the support substrate and the non-polar active region.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a sectional view illustrating a light emitting diode (LED) according to a first exemplary embodiment of the present invention.

FIG. 2a, FIG. 2b, FIG. 2c, FIG. 2d, FIG. 2e, FIG. 2f, and FIG. 2g are sectional views illustrating a method of fabricating an LED according to a second exemplary embodiment of the present invention.

FIG. 3a, FIG. 3b, FIG. 3c, and FIG. 3d are sectional views illustrating a method of fabricating an LED according to a third exemplary embodiment of the present invention.

FIG. 4 is a schematic plan view illustrating a photonic crystal structure.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

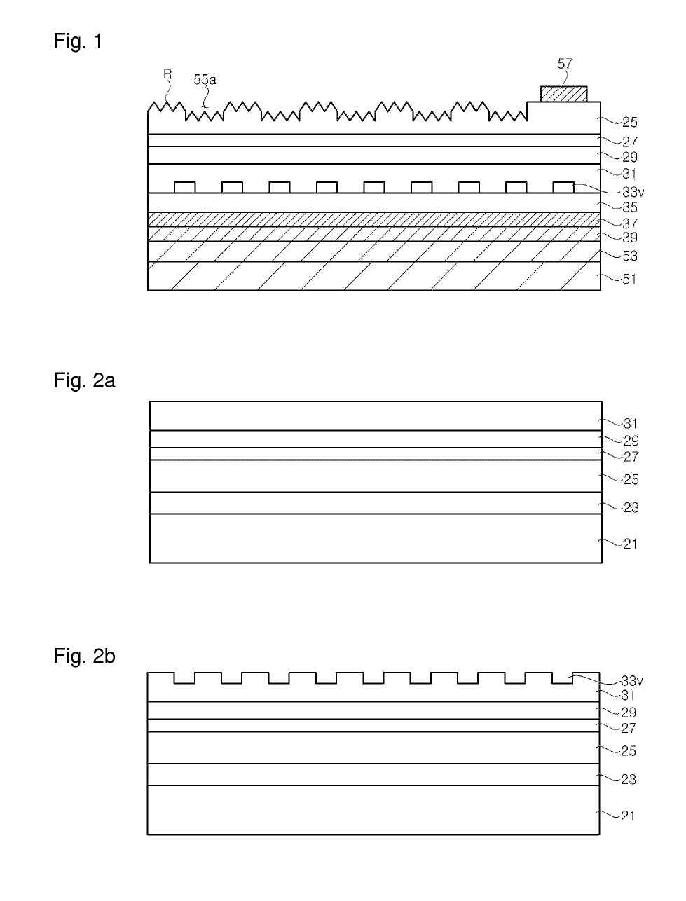

FIG. 1 is a sectional view illustrating a light emitting diode (LED) according to an exemplary embodiment of the present invention.

Referring to FIG. 1, the LED includes a support substrate 51, a lower semiconductor layer including layers 29, 31 and 35, an active region 27, an upper semiconductor layer 25 and a photonic crystal structure 33v. The LED may further include an ohmic contact layer 37, a protection layer 39, a bonding metal 53, and an upper electrode 57.

The support substrate 51 is distinguished from a growth substrate for growing compound semiconductor layers, and is a substrate attached to the previously grown compound semiconductor layers. In an exemplary embodiment, the support substrate 51 may be a sapphire substrate. The support substrate 51 may, however, be formed of various insulators or conductors.

The active region 27 may be formed of a III-N-based compound semiconductor, e.g., an (Al, Ga, In)N semiconductor, and the composition of the active region 27 may be controlled depending on the required wavelength of light. The active region 27 may include, for example, an InGaN well layer or an AlGaN well layer, and may have a single or multiple quantum well structure.

The active region 27 is non-polar, and may include a well layer grown on, for example, an m-plane (1100) or a-plane (1120). The active region 27 may be formed by growing epitaxial layers on an m-plane or a-plane GaN substrate, or may be formed by growing epitaxial layers on an m-plane or r-plane sapphire substrate.

Meanwhile, the lower semiconductor layer is positioned between the active region 27 and the support substrate 51, and may be composed of a plurality of layers. In this embodiment, the lower semiconductor layer may be a p-type semiconductor layer doped with Mg, and may include an electron blocking layer 29, a p-type optical layer 31 and a p-type contact layer 35. Here, the electron blocking layer 29 may be an AlGaN layer, and the p-type optical layer 31 may be an AlGaN layer or GaN layer. The p-type contact layer 35 may be an AlInGaN layer or GaN layer. The p-type contact layer 35 may be formed to have a thickness of about 200 nm or less. In this embodiment, the lower semiconductor layer may further include other functional layers (not shown).

Meanwhile, the photonic crystal structure includes a pattern of voids 33v arranged along a surface of the support substrate 51. The refractive index of the photonic crystal structure is changed in a regular manner by the voids 33v. Hereinafter, the pattern of the voids 33v will be described as a photonic crystal structure 33v.

The photonic crystal structure 33v is embedded in the lower semiconductor layer. That is, the photonic crystal structure 33v is positioned within the lower semiconductor layer. As shown in this figure, the photonic crystal structure 33v may be formed in the p-type AlGaN layer 31, and may be covered with the p-type contact layer 35. Thus, the photonic crystal structure 33v may be disposed near an interface between the p-type contact layer 35 and the p-type optical layer 31. The photonic crystal structure 33v reflects the light which is generated in the active region 27 and then travels toward the support substrate 51, and radiates the light which is guided within the semiconductor layers toward the upper semiconductor layer 25.

As shown in FIG. 4, the voids 33v may each be formed to have a stripe shape, and may be arranged parallel to one another. The width W and height of each of the voids 33v is less than about ½ of the wavelength of the light generated in the active region 27, and may, for example, be in a range from 50 to 200 nm. Meanwhile, the distance Sp between two adjacent voids 33v may be in a range from 50 nm to 1 μm.

Meanwhile, the direction of the stripe-shaped voids may be determined depending on the growth surface of the semiconductor layer. For example, if the active region includes an m-plane well layer, the voids 33v are arranged parallel to an a-direction. If the active region includes an a-plane well layer, the voids 33v are arranged parallel to a c-direction. Here, the a-direction and c-direction represent directions normal to the a-plane and c-plane, respectively.

The voids are arranged along the growth surface of the semiconductor layer, as described above, so that it is possible to improve the polarization ratio of the polarized light superiorly radiated along the growth surface. That is, the non-polar LED grown on the m-plane emits polarized light in which an electric field component (E//a) parallel to the a-direction is stronger than an electric field component (E//c) parallel to the c-direction. Thus, the stripe-shaped voids are aligned parallel to the a-direction, so that it is possible to improve the polarization ratio of the non-polar LED by restricting the electric field component (E//c) parallel to the c-direction and reinforcing the electric field component (E//a) parallel to the a-direction. In addition, the non-polar LED grown on the a-plane emits a polarized light in which an electric field component (E//c) parallel to the c-direction is stronger than an electric field component

(E//m) parallel to the m-direction. Thus, the stripe-shaped voids are aligned parallel to the c-direction, so that it is possible to improve the polarization ratio of the non-polar LED by restricting the electric field component (E//m) parallel to the m-direction and reinforcing the electric field component (E//c) parallel to the c-direction.

Meanwhile, the upper semiconductor layer 25 is positioned on the active region 27. The upper semiconductor layer 25 includes an n-type contact layer 25, and may further include other functional layers (not shown). The n-type contact layer 25 may be, for example, an n-type GaN layer or n-type AlGaN layer doped with Si. The entire thickness of the upper semiconductor layer 25 may be approximately 2 to 4 μm.

A surface R of the upper semiconductor layer 25 may be roughened. A pattern of recesses 55a may also be formed on the surface of the upper semiconductor layer 25, and the roughened surface R may be formed inside and outside the recesses 55a. The upper electrode 57 may be positioned on the upper semiconductor layer 25.

Meanwhile, the ohmic contact layer 37 forms an ohmic contact with the p-type contact layer 35. The ohmic contact layer 37 may include, for example, Ni. The ohmic contact layer 37 may also include a reflection layer, e.g., an Al layer or an Ag layer. Further, the protection layer 39 may cover the ohmic contact layer 37 so as to protect the ohmic contact layer 37. The protection layer 39 may be formed, for example, of a metal layer such as Ni. Meanwhile, the support substrate 51 may be bonded to a side of the lower semiconductor layer, e.g., the protection layer 39 through the bonding metal 53 which may be made of, e.g., AuSn.

According to this exemplary embodiment, the photonic crystal structure 33v is embedded within the lower semiconductor layer, so that it is possible to prevent the loss of light generated by traveling toward the support substrate 51, thereby improving the light emitting efficiency of the LED. Further, the stripe-shaped voids 33v are aligned corresponding to the growth direction of the non-polar semiconductor layer, thereby improving the polarization ratio of the non-polar LED.

Meanwhile, in this exemplary embodiment, if the support substrate 51 is a conductive substrate, the support substrate 51 may be used as a lower electrode, or a lower electrode may be formed under the support substrate 51. On the other hand, if the support substrate 51 is an insulative substrate, a lower electrode is formed above the support substrate 51 so as to be electrically connected to the ohmic contact layer 37.

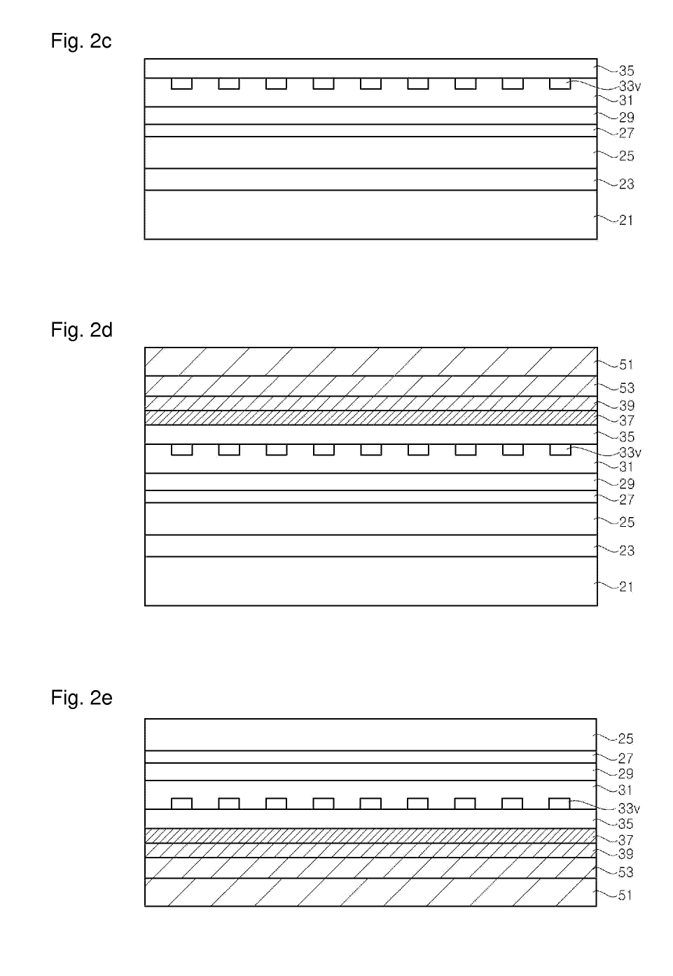

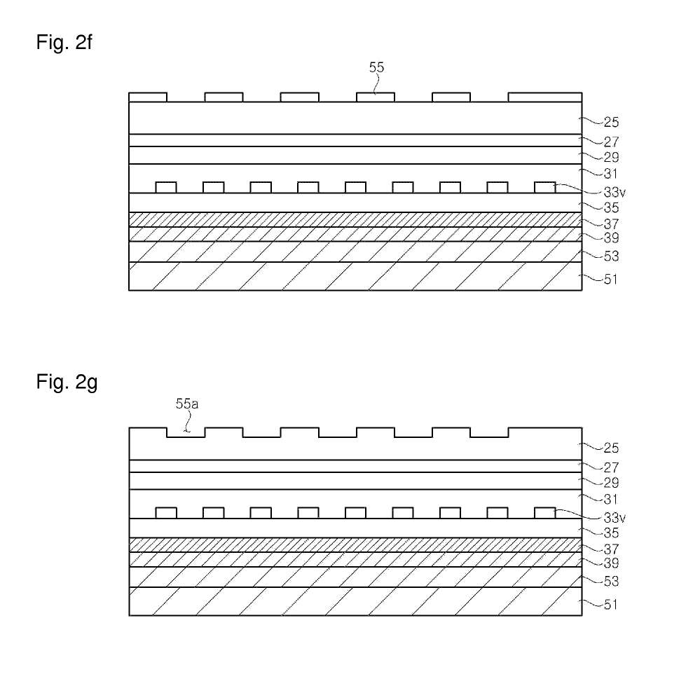

FIGS. 2a to 2g are sectional views illustrating a method of fabricating an LED according to another exemplary embodiment of the present invention.

Referring to FIG. 2a, non-polar epitaxial layers including a first conductive semiconductor layer 25, an active region 27 and a second conductive semiconductor layer are formed on a growth substrate 21. The first conductive semiconductor layer 25 may include, for example, an n-type contact layer 25, and the second conductive semiconductor layer may include an electron blocking layer 29 and a p-type optical layer 31.

The growth substrate 21 is not particularly limited as long as GaN-based non-polar semiconductor layers can be grown on the growth substrate 21. The growth substrate may be substrate made of, for example, sapphire, SiC, spinel, Si, GaN, GaO, ZnO or the like. Particularly, an m-plane sapphire substrate or m-plane GaN substrate may be used to grow an m-plane GaN-based non-polar semiconductor layer, and an r-plane sapphire substrate or a-plane GaN substrate may be used to grow an a-plane GaN-based non-polar semiconductor layer.

The composition of the active region may be controlled depending on the required wavelength of light. For example, the active region may include an InGaN well layer so as to emit blue light, or may include an AlGaN well layer so as to emit deep ultraviolet (DUV) light. The first conductive semiconductor layer 25 may include an n-type contact layer 25, and the electron blocking layer 29 may be formed of an AlGaN layer. The p-type optical layer 31 may be formed of a GaN layer or AlGaN layer doped with Mg. The non-polar epitaxial layers may be formed using a metal organic chemical vapor deposition (MOCVD) or molecular beam epitaxy (MBE) technique.

A buffer layer 23 may be formed before the first conductive semiconductor layer 25 is formed on the growth substrate 21. The buffer layer 23 may be formed of, for example, GaN or AN. Further, other functional layers, e.g., an n-type clad layer and the like, may be added as required.

Referring to FIG. 2b, a pattern of voids 33v is formed in the second conductive semiconductor layer, e.g., the p-type optical layer 31. The voids 33v may be formed by forming a photoresist pattern on the p-type optical layer 31 using a nano-imprinting technique and partially etching the p-type optical layer 31 using the photoresist pattern as an etching mask. The p-type optical layer 31 may be etched, for example, through a wet etching using a phosphoric acid-based solution. After the etching is completed, the photoresist pattern is removed. The voids 33v may be partially formed in the p-type optical layer 31 so as to prevent the active region 27 from being damaged while the voids 33v are formed.

The voids 33v are formed to constitute a photonic crystal structure. Further, in order to improve the polarization ratio of the non-polar LED, the voids 33v may have a strip shape as shown in FIG. 4, and may be aligned parallel to a specific direction corresponding to the growth direction of the epitaxial layer. For example, if the epitaxial layers are grown on the m-plane, the voids 33 may be arranged parallel to the a-direction. If the epitaxial layers are grown on the a-plane, the voids 33 may be arranged parallel to the c-direction. At this time, the width W and height of each of the voids 33v may be less than ½ of the wavelength of the light emitted in the active region 27, e.g., in a range from 50 to 200 nm, and the distance between two adjacent voids 33 may be less than twice the wavelength of the light, e.g., in a range from 50 nm to 1 μm.

Referring to FIG. 2c, after the pattern of the voids 33v is formed, a second conductive contact layer 35 for covering the pattern of the voids is formed by re-growing a semiconductor layer. The second conductive contact layer 35 is formed with a semiconductor layer which may form an ohmic contact with a metal, wherein the second conductive contact layer 35 may be formed of, for example, a p-type GaN or a p-type AlInGaN. Before the second conductive semiconductor layer 35 is formed, another p-type semiconductor layer may be additionally formed.

Referring to FIG. 2d, an ohmic contact layer 37 and a protection layer 39 are formed on the second conductive contact layer 35, and a support substrate 51 is bonded to the protection layer through a bonding metal 53.

The ohmic contact layer 37 may be formed of a metallic material or transparent conductive layer which comes in ohmic contact with the p-type contact layer 35, and the ohmic contact layer 37 may include Ni. The ohmic contact layer 37 may include a reflection layer such as Al or Ag. The protection layer 39 is formed to protect the ohmic contact layer 37 from the bonding metal, and the protection layer 39 may be formed of, for example, Ni. The bonding metal 53 is used to bond the substrate 51 to the protection layer 39, and the bonding metal 53 may be formed of AuSn.

Referring to FIG. 2e, after the support substrate 51 is bonded to the protection layer 39, the growth substrate 21 is removed, and the first conductive semiconductor layer 25, e.g., the n-type contact layer 25, is exposed.

The growth substrate 21 may be removed using a laser lift-off (LLO) or may be removed by an etching or polishing technique. After the growth substrate 21 is removed, the buffer layer 23 is also removed so that a surface of the n-type contact layer 25 is exposed.

Referring to FIG. 2f, a photoresist pattern 55 for defining recess regions may be formed on the exposed n-type contact layer 25. Subsequently, as shown in FIG. 2g, the n-type contact layer 25 is partially etched using the photoresist pattern 55 as an etching mask, thereby forming recesses 55a.

Subsequently, the surface R of the n-type contact layer 25 having the recesses 55a formed therein may be roughened. The roughened surface R may be formed using a photolithography process or using a wet or dry etching technique using, e.g., metallic nano-particles. Meanwhile, an upper electrode 57 is formed on the n-type contact layer 25, thereby completing an LED as shown in FIG. 1.

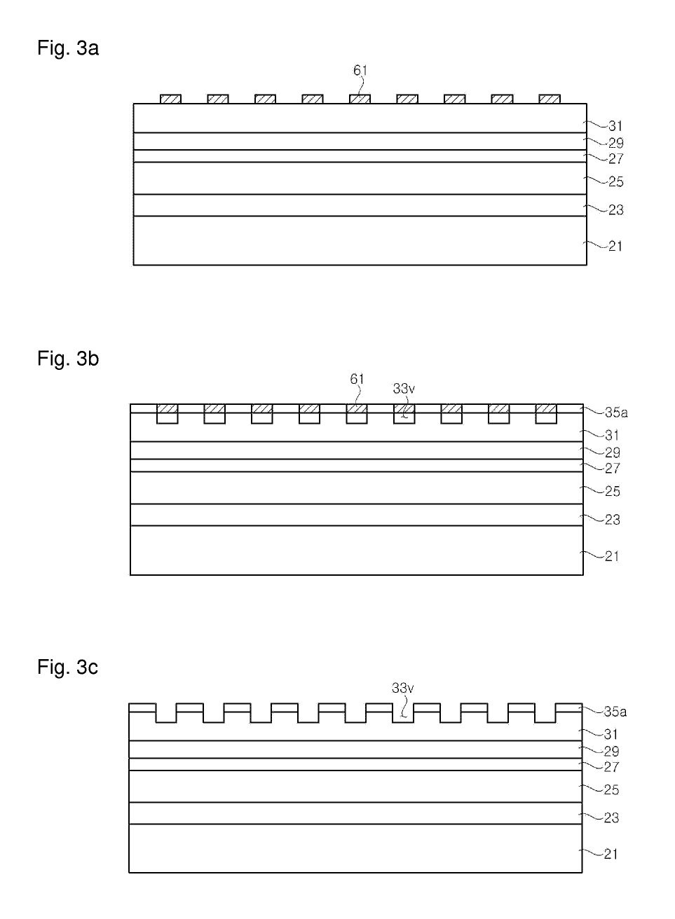

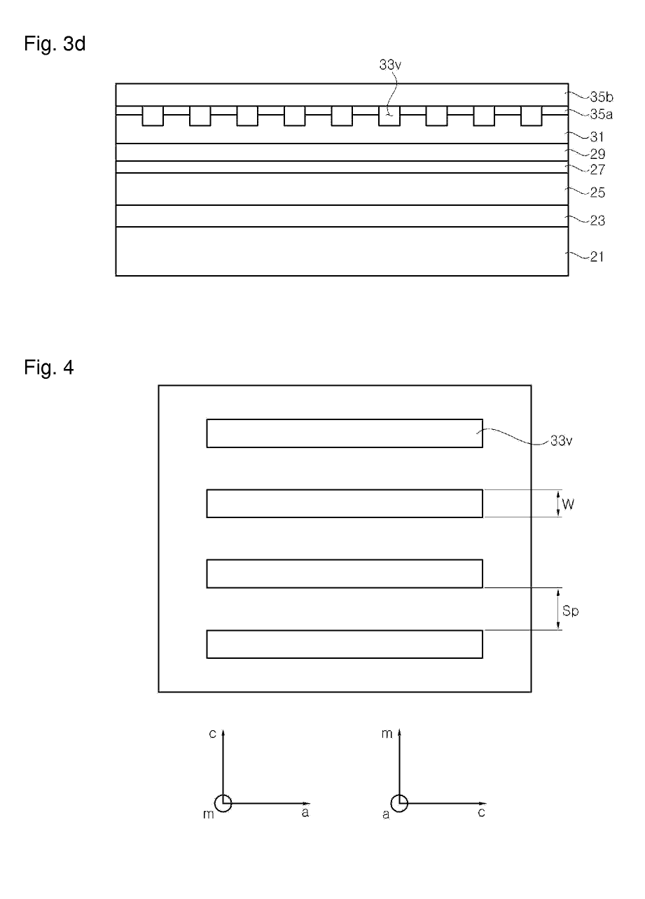

FIGS. 3a to 3d are sectional views illustrating a method of fabricating an LED according to another exemplary embodiment of the present invention. Here, another method of forming voids 33v is disclosed.

Referring to FIG. 3a, a first conductive semiconductor layer 25, an active region 27 and a second conductive semiconductor layer including layers 29, 31 are formed on a growth substrate 21, as described with reference to FIG. 2a. Subsequently, a metal pattern 61 is formed on a p-type optical layer 31. The metal pattern 61 may be formed of a metal that reacts with a GaN-based semiconductor layer to form a nitride. The metal pattern 61 may be formed of, for example, at least one metallic material selected from Ta, Ti and Cr, or alloy thereof.

Referring to FIG. 3b, a p-type layer 35a such as a GaN layer or AlInGaN layer is grown after the metal pattern 61 is formed. For example, the p-type layer 35a may be grown by loading the growth substrate 21 into a reaction chamber, increasing the temperature of the growth substrate 21 to a temperature for growing a GaN-based semiconductor layer and then injecting a nitrogen source gas such as NH₃ into the reaction chamber. At this time, a metal nitride is formed through a reaction between the metal pattern 61 and nitrogen in a p-type optical layer 31. Since the metal nitride is unstable at a temperature of about 900° C. or higher, the metal nitride is evaporated into the gas. Accordingly, voids 33v are formed under the metal pattern 61. Meanwhile, Ga or the like, decomposed in the p-type optical layer 31, reacts with the NH₃ gas, thereby forming the p-type layer 35a. Thus, the p-type layer 35a can be formed without supplying a Ga source such as TMG.

The voids 33v are formed corresponding to the metal pattern 61. Thus, the metal pattern 61 is formed as a pattern having the shape of stripe-shaped long rods, thereby forming the stripe-shaped voids as shown in FIG. 4.

The p-type layer 35a is grown on the p-type clad layer 31 having the metal pattern 61 exposed therefrom so as to cover the side surface of the metal pattern 61. The p-type layer 35a may also cover a portion of the top surface of the metal pattern 61.

Referring to FIG. 3c, after the voids 33v are formed, the remaining metal pattern 61 is removed. The metal pattern 61 may be removed using an ultraviolet cleansing technique. Alternatively, the metal pattern 61 may be removed using an ultra cleaning technique in a solution in which the metal pattern 61 may be dissolved but the GaN-based semiconductor layer may not be dissolved. In this case, the solution may be, for example, water, hydrochloric acid, water and hydrochloric acid, sulfuric acid, water and sulfuric acid, nitric acid, water and nitric acid, hydrofluoric acid, water and hydrofluoric acid, water and sodium hydroxide, water and potassium hydroxide (water has a composition ratio of 0 to 90%), or the like.

Referring to FIG. 3d, a p-type contact layer 35b is formed to cover the voids 33v. The p-type contact layer 35b may be formed with a GaN layer or AlInGaN layer, and may be formed of the same material as the p-type layer 35a.

Subsequently, processes as described with reference to FIGS. 2d to 2g are performed, thereby completing an LED.

According to this exemplary embodiment, since the metal pattern 61 is used to form the voids 33v, the pattern of the voids 33v can be precisely formed, and wet etching is not required to etch the semiconductor layer.

As described above, according to exemplary embodiments of the present invention, a photonic crystal structure embedded in a lower semiconductor substrate between a support substrate and an active region is formed, so that it is possible to prevent light from being lost in the lower semiconductor layer, thereby improving light emitting efficiency of the non-polar LED. Further, the photonic crystal structure is formed using stripe-shaped voids, thereby improving the polarization ratio of the non-polar LED.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A non-polar light emitting diode (LED), comprising:
a substrate;
a lower semiconductor layer disposed on the support substrate;
an upper semiconductor layer disposed on the lower semiconductor layer;
a non-polar active region disposed between the lower semiconductor layer and the upper semiconductor layer; and
a photonic crystal structure embedded in the lower semiconductor layer.

2. The non-polar LED of claim 1, wherein the lower semiconductor layer comprises a p-type contact layer, and the upper semiconductor layer comprises an n-type contact layer.

3. The non-polar LED of claim 2, wherein the photonic crystal structure comprises a pattern of voids aligned parallel to one another.

4. The non-polar LED of claim 3, wherein the width and height of each of the voids are in a range from 50 to 200 nm, and the distance between two adjacent voids is in a range from 50 nm to 1 μm.

5. The non-polar LED of claim 3, wherein the active region comprises an m-plane GaN-based well layer, and the voids are aligned parallel to an a-direction.

6. The non-polar LED of claim 3, wherein the active region comprises an a-plane GaN-based well layer, and the voids are aligned parallel to a c-direction.

7. The non-polar LED of claim 3, wherein the p-type contact layer is positioned between the voids and the substrate.

8. The non-polar LED of claim 1, wherein the upper semiconductor layer comprises a roughened surface.

9. The non-polar LED of claim 8, wherein the upper semiconductor layer comprises a pattern of recesses.

10. The non-polar LED of claim 1, further comprising an ohmic contact layer disposed between the lower semiconductor layer and the support substrate.

11. A method of fabricating a non-polar LED, comprising:
forming a first semiconductor layer, a non-polar active region and a second semiconductor layer on a first substrate;
forming a pattern of voids in the second semiconductor layer;
forming a conductive contact layer covering the pattern of the voids;
forming an ohmic contact layer on the conductive contact layer;
forming a second substrate on the ohmic contact layer; and
removing the first substrate, thereby exposing the first semiconductor layer.

12. The method of claim 11, wherein forming the pattern of voids comprises:
forming a photoresist pattern on the second semiconductor layer; and
partially etching the second conductive semiconductor layer using the photoresist pattern as an etching mask.

13. The method of claim 11, wherein forming the pattern of voids comprises:
forming a metal pattern on the second semiconductor layer;
reacting the metal pattern with the second semiconductor layer, thereby forming the pattern of voids under the metal pattern; and
removing residues of the metal pattern.

14. The method of claim 13, wherein the metal pattern comprises at least one metallic material selected from the group consisting of Ta, Ti and Cr.

15. The method of claim 11, wherein the voids comprise a stripe shape and are parallel to one another.

16. The method of claim 15, wherein the active region comprises an m-plane GaN-based well layer, and the voids are parallel to an a-direction.

17. The method of claim 15, wherein the active region comprises an a-plane GaN-based well layer, and the voids are parallel to a c-direction.

18. The method of claim 11, further comprising forming a roughened surface on the exposed first semiconductor layer.

19. The method of claim 17, further comprising forming a pattern of recesses by patterning the exposed first semiconductor layer, before forming the roughened surface.

20. The non-polar LED of claim 3, wherein each of the voids comprises a stripe shape.
